(19) United States
(12) Patent Application Publication
(10) Pub. No.: US 2025/0052787 A1
(43) Pub. Date: Feb. 13, 2025

(54) SIGNAL CONDITIONING STAGE

(71) Applicant: SYNAPTEC LIMITED, Glasgow (GB)

(72) Inventor: Pawel NIEWCZAS, Glasgow (GB)

(73) Assignee: SYNAPTEC LIMITED, Glasgow (GB)

(21) Appl. No.: 18/723,044

(22) PCT Filed: Dec. 22, 2022
(86) PCT No.: PCT/GB2022/053378

§ 371 Date: Jun. 21, 2024

(30) Foreign Application Priority Data
Dec. 23, 2021 (GB) 2118895.8

(51) Int. Cl. G01R 1/36; G01R 15/00; G01R 15/08; G01R 15/24; H02H 1/00

(52) U.S. Cl. CPC G01R 1/36; G01R 15/002; G01R 15/08; G01R 15/247; H02H 1/0007

(57) ABSTRACT

The invention provides a signal conditioning stage for a photonic current or voltage transducer which comprises a number of burden resistors and a number of switches in parallel with the burden resistors, the switches operable to short different burden resistors in response to detection of different currents or voltages, and thereby protect the burden resistors and/or adjust the dynamic range of the transducer. The invention enables a hybrid photonic current or voltage sensor with an extended measurement range and increased accuracy and signal-to-noise ratio at the lower measurement end. Embodiments of the invention provide a device that is capable of covering both protection and metering ranges, as may be defined and re-defined from time-to-time by relevant standards. The invention also enables an auto-ranging device which increases measurement performance at lower current by deliberately reducing the range for lower currents and increasing the range when certain current level is exceeded, increasing dynamic range without the need for multiple LVTs. Similar range switching allows dynamic range increases in voltage sensing applications too.

The present invention relates to the field of power transmission and distribution. More specifically, the present invention concerns improvements to optical voltage sensors and related arrangements which enable such sensors to be used for applications in power networks and exposed to the highest currents and voltages for equipment. In an embodiment of the invention there is provided a signal conditioning stage which protects an optical voltage sensor from abnormal, fault or test currents. A photonic current transducer, comprising a current transformer, a signal conditioning stage, and an optical voltage sensor, benefits from the protection and/or improved dynamic range provided by the signal conditioning stage.

### BACKGROUND TO THE INVENTION

It is desirable from a protection, control and monitoring perspective to be able to measure, in real-time, the voltages and currents on transmission or distribution networks that may comprise of overhead power lines or power cables. The points where it is desirable to perform measurements and/or monitor the condition of the power network are often very long distances (e.g. >50 km) from electricity substations or topside civil structures or are simply difficult to access.

In particular, there has to date been no reliable method by which such voltages can be measured over long distances without requiring a remote sensor, a local power supply and the means to communicate sensor data over the long distance. Generally speaking, methods of measuring such voltages require a sensor incorporating active electronics. Providing power to sensors at remote locations and ensuring reliability of the power supply is a significant problem.

Some approaches utilise copper pilot wires housed within the power cable to deliver power to sensors. These sensors may communicate the measured voltages back along an optical fibre also housed within the power cable. However, although the optical fibre permits long distance communication of measurement data, wire integration within the cable is an added complication (and adds to the cost) and is not applicable to overhead transmission lines. Accordingly, telecommunications equipment may be necessary to transmit the measurement data.

Alternatively, it is known to install transformers which transform the primary line voltage, which may be 10 to 30 kV, down to a low voltage, e.g. 24 to 240 V, to drive the sensor system. This approach is extremely costly as the transformers are expensive. Also, the sensor system powered by such means will stop operating when a fault on the primary system cuts off power to the sensor. A back up battery may be provided, but, again, this adds to the cost, complexity and reduces system reliability. Finally, various power scavenging methods can be utilised, but these are inferior for the same reasons. An approach utilising a passive sensor, not requiring a local power supply, would understandably be beneficial and superior to any of the techniques mentioned above.

Unfortunately, passive sensors which (for example) communicate and/or are interrogated via optical fibres are unsuitable for such applications because of their relatively low dynamic range. In theory, dynamic range could be improved by providing multiple such sensors but this has the effect of reducing bandwidth by a corresponding multiplier. Such devices also lack protection in the event of abnormal, fault or test currents which might cause catastrophic damage.

The Applicant's proprietary FBG-based optical fibre sensor (described in further detail below) addresses some of these deficiencies, for example by enabling passive measurement of voltage (and current) at remote locations without reliance on supporting infrastructure, power and/or GPS, but for some applications might not provide sufficient dynamic range. At low input voltage the range is limited by the signal-to-noise ration whereas at high voltage the range is limited by the voltage withstand of the sensor. Furthermore, for protection class devices, there is a requirement that the burden resistor of a current transformer has a resistance value such that the output voltage across the burden at fault condition (high current) is matched to the voltage withstand. However, the nominal current which needs to be measured with certain high accuracy may be some 20 or 30 times lower than this. For devices that need to cover both protection and metering ranges, the metering accuracy may need to exceed 0.2% of the full-scale output and this cannot be achieved using conventional means.

Accordingly, it is an object of at least one aspect of the present invention to obviate and/or mitigate one or more disadvantages of known/prior arrangements, for example the relatively low dynamic range which limits measurement capability and/or inability to cope with fault or test currents, and in embodiments thereof to reduce or eliminate the reliance on supporting infrastructure such as power supplies and telecommunications equipment.

Further aims and objects of the invention will become apparent from reading the following description.

### SUMMARY OF THE INVENTION

According to a first aspect of the invention, there is provided a signal conditioning stage for a photonic current or voltage transducer, the signal conditioning stage comprising at least one burden resistor (e.g. to transform a secondary current of a current transformer to a voltage measurable by an optical voltage sensor) and at least one switch in parallel with the burden resistor, whereby the switch is operable to short the burden resistor responsive to detection of a corresponding threshold current or voltage.

The signal conditioning stage might alternatively be referred to as a signal conditioning module.

The signal conditioning stage may be operable to short (and thereby to protect) the burden resistor (and/or the optical voltage sensor) only in the event of abnormal, fault or test currents. Alternatively, or additionally, the signal conditioning stage may be operable to automatically switch detection range so as to increase the dynamic range of the PCT/PVT.

Most preferably, the signal conditioning stage comprises a plurality of burden resistors and corresponding switches, each of the burden resistors preferably being different and each of the switches operable to short the corresponding burden resistor responsive to a different threshold current or voltage. In a preferred embodiment of the invention, the signal conditioning stage comprises two burden resistors and two corresponding switches.

Preferably, the signal conditioning stage is configured such that the or each switch is off by default to maximise the burden resistance of the signal conditioning stage at low input current.

Optionally, the or each switch comprises a solid-state switch. Optionally, the solid-state switch comprises one or more MOSFETs. Preferably, the solid-state switch comprises a bi-directional MOSFET switch (or solid-state relay).

Alternatively, the or each switch comprises a mechanical relay.

Optionally, the or each switch is controlled by an electronic driver. The electronic driver may comprise two or more Zener diodes selected for a desired current or voltage threshold. The electronic driver may also comprise one or more resistors and/or capacitors selected for a desired timing.

Alternatively, the or each switch is controlled by a comparator (or comparator stage). Preferably, the signal conditioning stage further comprises a threshold selection circuit (or stage) that provides a first input to the comparator (non-inverting input). Preferably, the signal conditioning stage further comprises a voltage regulator that provides a second input to the comparator (inverting input). Preferably, the signal conditioning stage further comprises a positive feedback to the comparator (non-inverting input) via a resistor selected to effect hysteresis sufficient to prevent switching oscillations (Schmitt trigger hysteresis).

Further alternatively, the or each switch may be controlled by a microcontroller. A single microcontroller may control all of the switches, or each switch might be controlled by a corresponding/dedicated microcontroller. The microcontroller (or microcontrollers) may be powered from a current transformer.

Embodiments of the first aspect of the invention may comprise features corresponding to the preferred or optional features of (or intended to put into effect the steps of) any other aspect of the invention or vice versa.

According to a second aspect of the invention there is provided a photonic current transducer comprising a current transformer, a signal conditioning stage according to the first aspect (which transforms a secondary current of a current transformer to a measurable voltage), and an optical voltage sensor comprising a fibre Bragg grating mechanically coupled to a piezoelectric actuator which expands and contracts responsive to the voltage across the burden resistor (or burden resistors) of the signal conditioning stage.

The current transformer may, for example, comprise a transformer with a ferromagnetic core or a Rogowski coil.

Similarly, according to a third aspect of the invention there is provided a photonic voltage transducer comprising a voltage transformer or (high) voltage divider, a signal conditioning stage according to the first aspect and an optical voltage sensor comprising a fibre Bragg grating mechanically coupled to a piezoelectric actuator which expands and contracts responsive to the voltage across the burden resistor (or burden resistors) of the signal conditioning stage.

To date, such optical voltage sensors have not been widely used for power transmission and distribution applications because the dynamic ranges of such sensors have been insufficient to meet the relevant standards.

Embodiments of the second and third aspects of the invention may comprise features corresponding to the preferred or optional features of (or intended to put into effect the steps of) any other aspect of the invention or vice versa.

According to a fourth aspect of the invention there is provided a monitoring system comprising:
one or more photonic current transducers according to the second aspect and/or one or more photonic voltage transducers according to the third aspect; and
an interrogator in optical communication with the one or more photonic voltage and/or current transducers via an optical fibre.

Preferably, the interrogator comprises a broadband light source to illuminate the optical fibre. Alternatively, the interrogator may comprise a scanning or tuneable laser to illuminate the optical fibre. The optical fibre may be comprised in a power cable, and the one or more photonic voltage transducers may be connected to the power cable. Preferably, the monitoring system comprises a plurality of photonic voltage and/or current transducers via the optical fibre and receives a corresponding plurality of optical signals. Each of the plurality of signals may comprise a wavelength unique to the corresponding photonic voltage or current transducer.

Preferably, the interrogator is configured to determine the or each sensed voltage from the received optical signal. Preferably, the or each sensed voltage is determined from a spectral position of a peak reflection wavelength from the or each fibre Bragg grating of respective photonic voltage transducers. Preferably, changes in the sensed voltage are determined from changes in the peak reflection wavelength.

Optionally, the interrogator is configured to identify changes in the sensed voltage which correspond to range-switching in a signal conditioning stage. The output from the interrogator can be adjusted or re-calibrated responsive to an identified range-switch. Optionally, the interrogator is configured to identify a power network fault at or near a particular photonic voltage or current transducer based on changes in the sensed voltage.

Preferably, the fibre Bragg grating of the or each photonic current and/or voltage transducer has a unique peak reflection wavelength, and the interrogator may comprise a wavelength division multiplexer. Alternatively, the interrogator may comprise a time division multiplexer.

Embodiments of the fourth aspect of the invention may comprise features corresponding to the preferred or optional features of (or intended to put into effect the steps of) any other aspect of the invention or vice versa.

### BRIEF DESCRIPTION OF THE DRAWINGS

There will now be described, by way of example only, embodiments of aspects of the invention with reference to the drawings (like reference numerals referring to like features), of which:

FIG. 1 illustrates a fibre Bragg grating based optical voltage sensor;

FIG. 2 illustrates an optical fibre sensor monitoring system;

FIG. 3t illustrates a high-voltage photonic current transducer;

FIG. 4 is a circuit diagram illustrating a basic protection circuit for a low voltage transducer such as that comprised in the photonic current transducer shown in FIG. 3;

FIG. 5 is a circuit diagram illustrating a protection circuit for a low voltage transducer according to the invention;

FIG. 6 is a circuit diagram illustrating an alternative protection circuit for a low voltage transducer according to the invention; and

FIG. 7 is a circuit diagram illustrating another alternative protection circuit for a low voltage transducer according to the invention; and

FIG. 8 is a circuit diagram illustrating yet another alternative protection circuit for a low voltage transducer according to the invention.

### DETAILED DESCRIPTION OF PREFERRED EMBODIMENTS

As discussed in the background to the invention above it is desirable to be able to measure, in real-time, voltages and currents on power networks at long distances and without the need for power supplies, reliance on GPS satellites or telecommunications networks. By utilising optical fibre, whether standalone, wrapped around overhead conductors, provided within the earth overhead conductor or as incorporated in modern power cables or otherwise, the invention allows measurement of high voltages and currents over very long distances (e.g. up to 100 km before signal boosting is required), without any requirement for power supplies, access to GPS satellites or indeed telecommunications equipment, at the measurement locations, with significantly increased metering and protection dynamic range.

### Fibre Bragg Grating Optical Fibre Sensor

By way of introduction and to provide context for the description of preferred and alternative embodiments which follow, FIG. 1 illustrates a sensor 1, which may alternatively be described as a photonic voltage transducer (PVT) and is an example of a low voltage transducer (LVT). The sensor 1 combines an optical strain sensor with a piezo-electric element to provide a mechanism for the measurement of voltage at a remote location. The optical strain sensor comprises a fibre Bragg grating (FBG) 3 which is written in the core of an optical fibre 7 using standard writing technologies (such as UV interference and masking). The FBG 3 will reflect at the Bragg wavelength, λ_{B}=2n∧, where n is the effective core index of refraction and ∧ the pitch of the grating. Accordingly, FBG 3 effectively acts as a wavelength-specific reflector; the peak reflection wavelength dependent on the periodicity of the variation in the refractive index in the fibre core (i.e. the pitch of the grating).

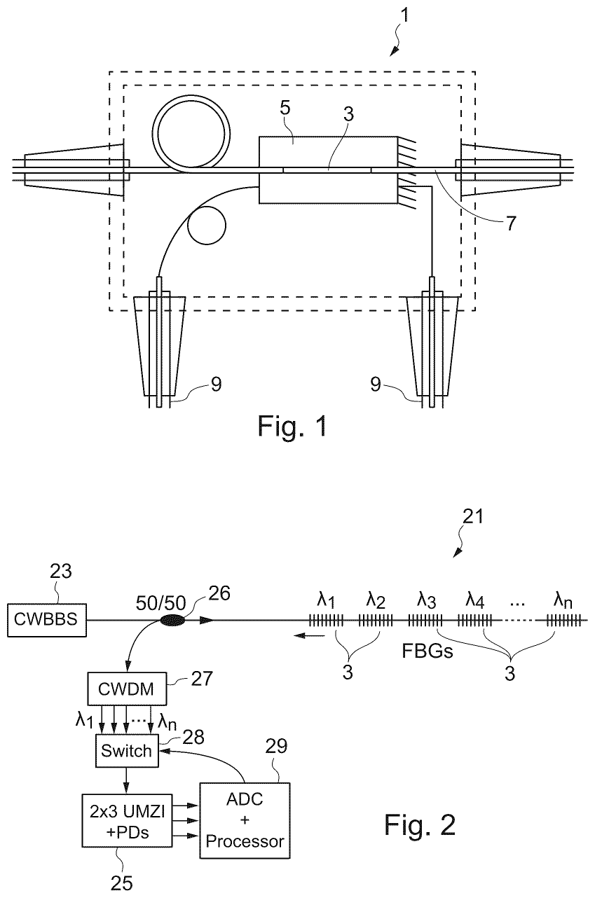

In this example a piezo-electric element 5 (which may be a piezo-electric stack) is in physical contact with (e.g. bonded to) the optical fibre in the region of the FBG 3. As the piezo-electric element 5 expands and contracts under an applied voltage (via terminals 9), the FBG 3 is also made to expand and contract thus altering the pitch of the grating and hence the Bragg wavelength. The instantaneous spectral position of the peak reflection wavelength of the FBG 3 is therefore indicative of the voltage applied to the piezo-electric element 5. Accordingly, a monitoring system (see below and FIG. 2) can be configured to determine the voltage applied to the piezo-electric element 5 using the instantaneous spectral position of the peak reflection wavelength.

In an alternative example, the FBG may not be attached directly to the piezo-electric element, and instead ‘strung’ between end caps that are attached to the piezo-electric element. In such an arrangement, the strain may be equalised over the grating, the fibre may be pretensioned, and the mechanical strain transfer may be increased, resulting in improved performance compared to the direct attachment arrangement above.

UK U.S. Pat. No. 2,590,909 (University of Strathclyde) discloses an alternative photonic voltage transducer (PVT) which, in one embodiment, employs an optical voltage sensor which comprises two ferroelectric hard piezoelectric discs bonded together to form a piezo-electric actuator, sandwiched between a pair of invar electrodes. The optical strain sensor, which as above comprises a fibre Bragg grating (FBG) written in the core of optical fibre, is mechanically coupled to the piezo-electric actuator via quartz strain-amplifying bridges which are bonded to respective electrodes. The quartz bridges each comprise a groove through which the fibre runs, and the fibre is bonded to the bridges. The purpose of the bridges is to limit the length of the fibre being strained to the area where the FBG is written in order to maximise the effect of the movement of the electrodes which otherwise would unnecessarily strain more of the fibre and result in smaller wavelength shifts. This, in effect, amplifies the strain imparted on the FBG.

Such sensors may also be employed as a current sensor by connecting the piezoelectric element and bonded FBG in parallel with a current transformer (CT) and a burden resistor. Monitoring the secondary current of the CT, transformed into a voltage via the burden resistor, provides a measure of the primary current in a cable enclosed by the CT. A Rogowski coil, which has a dielectric core, may be used in place of the CT. Such a current sensor might be described as a photonic current transducer (PCT).

### Optical Fibre Sensor Monitoring System

FIG. 2 illustrates in schematic form a monitoring system 21 suitable for monitoring a plurality (n) of FBGs 3 in an optical fibre 11. Each FBG 3 is sensitive to a different wavelength of light (λ₁, λ₂, λ₃, λ₄ . . . λₙ) by appropriate selection of the periodicity of the variation in the refractive index of the fibre core (i.e. the pitch of the grating—see above), and each wavelength and/or FBG can be associated with a specific photonic voltage (or current) transducer (PVT/PCT).

The system comprises a broadband light source 23 for illuminating the optical fibre 11 with an interrogation signal which has a wavelength range covering the reflection wavelengths of all the FBGs 3 located along the optical fibre 11. Light passes along the fibre 11 and light reflected from each of the FBGs 3 (at each of the PVT/PCTs) is simultaneously and continuously fed into a wavelength division multiplexer 27 (via a coupler 26) which separates light received from the optical fibre 11 into a plurality of wavelengths (and associated fibres) each corresponding with one of the FBGs 3. A fast optical path switch 28, driven by ADC/Processor unit 29, guides the reflected signal from each FBG 3 in turn to an interferometer and demodulation platform 25.

The ADC/Processor unit 29 then processes the output from the interferometer and demodulation platform 25 to determine the wavelength of the reflected light in each channel and thereby determine the instantaneous voltage being applied to the piezo-electric element associated with the respective FBG 3 (and representative of the voltage sensed by the PVTPCT). This can be done, for example, by comparing the instantaneous spectral position of the reflection peak with calibration data or a look-up table.

Alternatively, a time division multiplexer (not shown) can be used to separate light received from the optical fibre 11 into a time-separated series. In such an arrangement, the FBGs 3 are not required to exhibit unique peak reflection wavelengths. A combination of time division and wavelength division multiplexing techniques may be used to interrogate very large arrays of FBGs (and, hence, very large arrays of PVTs/PCTs).

Reference numeral 31 generally indicates an interrogator which comprises the broadband light source 23, wavelength division multiplexer 27 and fast optical path switch 28 driven by ADC/Processor unit 29 (which could be replaced with or supplemented by a time division multiplexer), and interferometer and demodulation platform 25.

### Transducer Protection Circuit

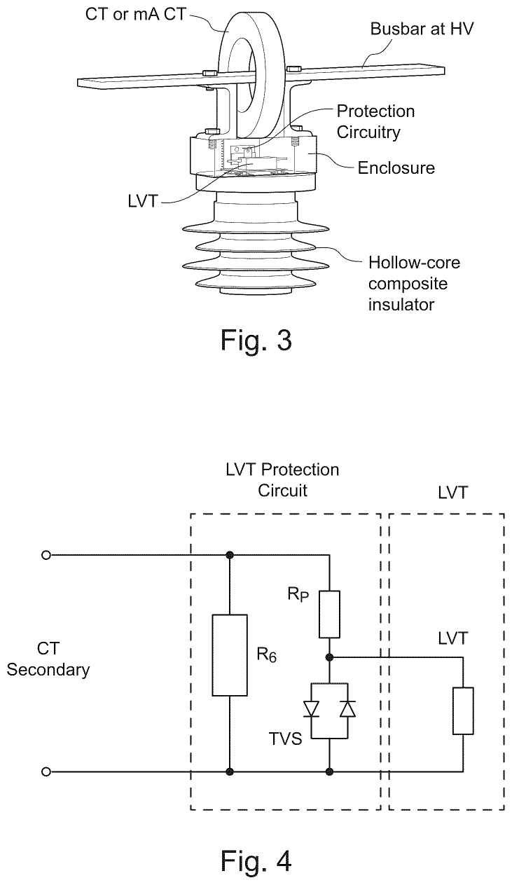

Piezo-electric sensors are fragile and although it has developed robust PVT/PCTs the Applicant has developed circuitry to protect the piezoelectric element in such devices. FIG. 3 is a schematic illustration of a high-voltage photonic current transducer (PCT) which incorporates a current transformer and a low voltage transducer (LVT) of the photonic type (i.e. PVT) shown in FIG. 1. Within the enclosure is located protection circuitry, between the current transformer and the low voltage transducer, to protect the piezoelectric element against overvoltage (i.e. exposure to voltages above the design voltage).

While manufacturers of piezo-electric transducers might recommend pre-loading to prevent excessive internal stresses within the material due to rapid contraction, this would be extremely difficult to realise within the kinds of compact packages which are enabled by the above-mentioned sensor methodologies.

Alternatively, an overvoltage spark gap (or gas discharge tube) could be connected in parallel with the piezo-electric element but this again would be difficult to realise within a compact package, and would protect against voltage level but not large slew rates which still lead to excessive accelerations. Furthermore, overvoltage spark gaps may be prohibitively expensive and may contain radioactive elements.

FIG. 4 is a circuit diagram showing a basic LVT protection circuit which would prevent damage to an LVT (such as shown in FIG. 1 and FIG. 3); the LVT protection circuit comprises a simple voltage divider in parallel with the burden resistor and the current transformer, with a transient voltage suppressing (TVS) diode to prevent damage to the LVT. This works by limiting the voltage across the LVT to the clamping voltage of the TVS diode.

### Withstand Requirements and Dynamic Range

A limitation of the basic LVT protection circuit shown in FIG. 4 is that for power transmission and distribution applications the burden resistor must be able to withstand significant loads. The burden must also be significantly greater than in standard applications (on the orders of 1 or 10Ω for example) and this can result in excessive heat dissipation (several kW) if exposed to a fault current or indeed a test current. Another disadvantage is that such a burden will result in an excessive footprint and increased bulk which is counter to the particular benefits of the Applicant's PCT/PVTs.

By way of example, the current withstand requirements for protection IEDs used on the Scottish Hydro Electric Transmission Network is summarised in the table below:

| | time [s] |
|---|---|
| 4x Nominal | continuous |
| 5x Nominal | 180 |
| 50x Nominal | 3 |
| 100x Nominal | 1 |

What this means, in summary, is that the burden or protection resistor must be able to withstand 4× the nominal current indefinitely, 5× the nominal current for at least 180 seconds, 50× the nominal current for at least three seconds, and 100× the nominal current for 1 second. It will be appreciated that this cannot be easily achieved by conventional means.

IEC standards also determine what constitutes a useable signal. The dynamic range of the Applicant's PCT (and indeed any sensor or transducer used for this purpose) is limited by the maximum voltage the LVT can withstand and the noise floor (e.g. of an interrogator such as described above). By way of example, the Applicant limits the maximum voltage on the LVT to ˜20 V rms. Useable signals at low voltage must be above the error levels dictated by the IEC standards.

In practice, metering accuracy of 0.2 is readily achievable if the nominal voltage is close to the LVT limit. Indeed half of the limit (˜10 V rms) will meet the 0.2 metering accuracy requirement (with a buffer). However, protection accuracy (5P) is only achievable for a nominal voltage closer to ˜1 V rms, which means that it is not currently possible to achieve the required metering accuracy and protection accuracy. One solution to this problem, identified by the Applicant, would require oversized components and a large heat sink to dissipate heat. This is impractical. Alternatively, another solution to this problem is to employ separate PCTs with their own separate current transformers, burden resistors and respective LVTs, but this reduces optical bandwidth by 50% and increases footprint by 100% (with commensurate increase in cost).

### Signal Conditioning Stage

Having identified these problems, and summarised them succinctly above, the Applicant has solved them in a manner which at least avoids what would otherwise be a reduction of optical bandwidth and increase of footprint, and in embodiments may in fact reduce the footprint while conserving optical bandwidth.

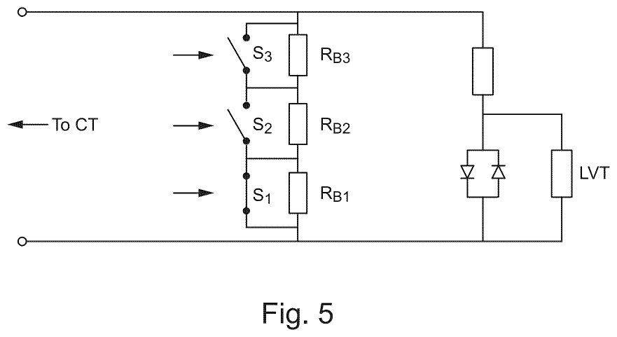

FIG. 5 illustrates a novel protection circuit, which may alternatively and functionally be described as a signal conditioning stage, to be used (as an alternative to the LVT protection described above with reference to FIG. 4) at the input terminals of an LVT. The signal conditioning stage (SCS) comprises a switched resistor network which in this example comprises three different burden resistors RB1, RB2 and RB3 which are connected in series. In parallel with each of the burden resistors is a switch S1, S2 and S3 (respectively), which in this embodiment are solid state switches (e.g. MOSFETs).

When the LVT is configured as a current sensor, as shown, the resistor network is connected in parallel with a current transformer output. At low input current (and by default), the resistor network is configured such that all of the switches S1, S2 and S3 are off such that the combined burden resistance (RB1+RB2+RB3) is maximised. As the current increases, the switches latch in sequence so as to short out the burden resistors RB1, RB2 and RB2 in turn, proportional to the rise in current. As such, the output voltage of the resistor network is limited or maintained so as to avoid exceeding the maximum voltage withstand of the LVT.

It is important to realise that the invention is not limited to current sensing applications. When the LVT is configured as a voltage sensor, not shown, the resistor network is configured as a resistive voltage divider, for example as a series of different burden resistors connected in series with a voltage transformer output or voltage divider output. As above, in parallel with each of the burden resistors is a switch. The resistor network is configured such that at low input voltage (and by default) all switches are off, thus the voltage signal across the output resistor (i.e. that seen by the LVT) is maximised. As the input voltage increases, the switches latch in sequence, proportional to the rise in input voltage, thereby limiting or maintaining the voltage across the output resistance.

In short, the switched resistor network allows LVT-based measurement sensitivity to be increased for very small inputs, and scaled down for large inputs. For example, at low currents, switches S1, S2 and S3 may be off to maximise the voltage across the LVT. At medium currents, switch S1 may be on and switches S2 and S3 off, to limit the voltage across the LVT. At high currents switches S1 and S2 may be on and S3 off, to limit the excess voltage across the LVT. In the case of abnormal, fault or test currents, all switches may be on to eliminate overheating of the burden resistor and protection resistor.

A preferred embodiment of the invention, which helps to explain the practical benefit of the signal conditioning stage, includes two burden resistors and two switches. While the burden resistors could be the same, in practice it is preferred that they are different and in this embodiment one burden resistance is about ten times greater than the other.

Correspondingly, one threshold would be about ten times smaller than the other, which should be sufficient to comply with both metering and protection IEC classes. In other embodiments, for example when necessary to measure ultra-high fault currents, three (or more) burden resistors may be necessary,

It is observed that rapid switching (responsive to current fluctuations) will give rise to discontinuous changes in the optical signal received by an interrogator (see “Optical Fibre Sensor Monitoring System” above), as compared to relatively slow fluctuations on the power network itself. These changes can be detected and identified as instances of range-switching, and the output from the interrogator can be adjusted or re-calibrated accordingly, preferably in real-time (on-the-fly). It is envisaged that this can be done without the need to know (or at least without communicating) which switches have been actuated, for example by historical analysis of the optical signal. This determination (of which burden(s) is (are) switched in or out) is of course made easier if there are few (e.g. only two) burden resistors, but this shall not limit the invention to a specific number of burdens. Such analysis might also indicate to a control system or the like that a power network fault has occurred.

Where the switches are controlled by a microcontroller (see below) or the like it is envisaged that the status of the switches (i.e. which are on and which are off) can be actively communicated to an interrogator, or it may be that just the detection range or an indication that the detection range has changed is communicated. This might be via the optical fibre for example.

As intimated above, it is envisaged that any number of burden resistors (and paired switches) might be employed in an SCS according to the invention, three being described above purely by way of illustrative example (and two mentioned only as a preferred, i.e. optional, embodiment). It is also envisaged that any suitable switch might be used in place of a solid state switch, such as a mechanical relay or other kind of electronic switch.

The switches may be controlled in any suitable manner, but it is preferred that the switches are controlled by a simple passive driver or active comparator circuit. Alternatively, the switches might be controlled by a more complex circuit such as a microcontroller. A microcontroller might be powered from a current transformer (which might be the CT of the PCT, or a separate CT).

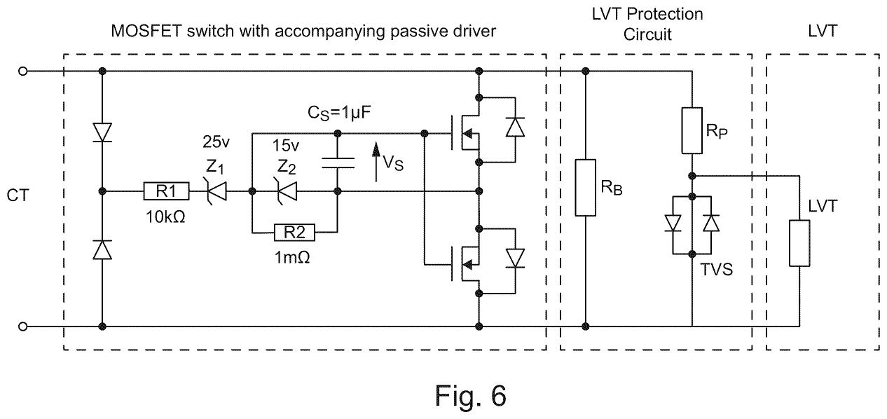

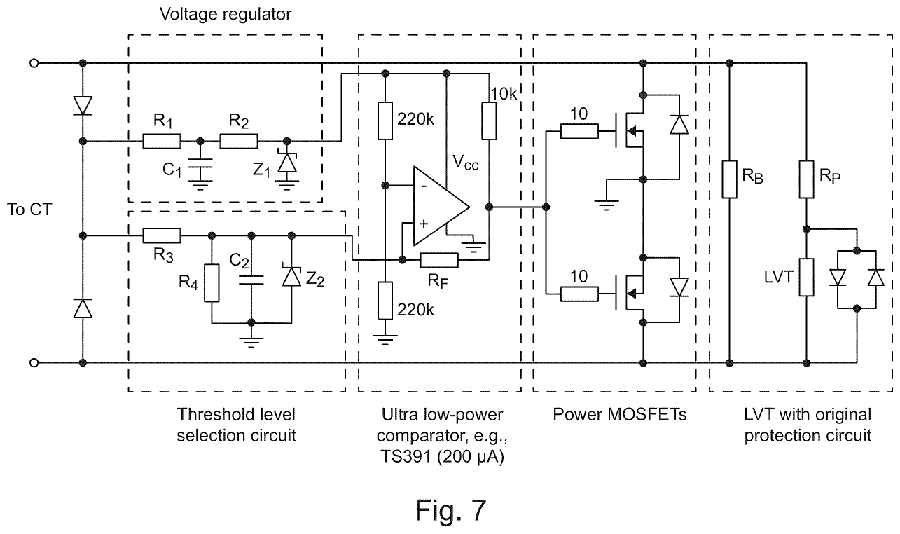

The embodiment shown in FIG. 5 is a relatively simple representation of the invention for the purposes of explaining the underlying concept above; there will now be described with reference to FIG. 6 an embodiment of the invention which comprises an electronic driver, and subsequently with reference to FIG. 7 an embodiment of the invention which comprises a comparator.

As intimated above, any number of burden resistors might be employed, and the embodiment shown in FIG. 6 comprises an LVT protection circuit having a single burden resistor RB. Connected in parallel with the burden resistor is a switching stage comprising a bi-directional MOSFET switch (or solid state relay) with an electronic driver. MOSFETs are a particularly useful and effective example of a solid-state switch suitable for implementing the present invention. MOSFETs are voltage-controlled, do not require current, and are close to an ideal switch for the purposes of this embodiment. High-performance power MOSFETs are available which accommodate high current with mΩ “on” states and MΩ “off” states, and very fast switching. In the arrangement shown, the electronic driver comprises two Zener diodes Z1,Z2 which are selected for a desired current threshold (the skilled person will be able to make an appropriate selection based on threshold as well as the chosen MOSFETs, as well as R1, R2 and CS to achieve the desired timing).

The embodiment shown in FIG. 7 also comprises an LVT protection circuit having a single burden resistor RB. Connected in parallel with the burden resistor is a switching stage comprising a pair of power MOSFETs (again functioning as a solid state relay), in this case driven by a comparator stage comprising an ultra low-power comparator (such as an STMicroelectronics TS391). Input to the comparator stage comes from a threshold level selection stage, and voltage within the circuit overall is regulated at a voltage regulator stage. This arrangement constitutes an active driver with an ultra low-power comparator and Schmitt trigger. In the specific configuration shown, the voltage regulator provides power within a predetermined time from fault or excess current initiating (e.g. within 5 ms) which is sufficient to power the circuit for the desired duration (e.g. just over 3 s). The comparator threshold (V−) is set at ½Z1 (e.g. 5 V). The threshold selection stage is configured to set the precise level and timing of switching by appropriate selection of R3, R4 and C2. For example, for 1 A nominal current and 5P20 protection class (IEC standard) it is desirable to set a threshold level at 22 A (31.1 V). This would set the comparator voltage (V+) at ½Z1, matching the comparator threshold (V−) and triggering the MOSFETs for the desired duration (just over 3 s). Schmitt trigger hysteresis, adjusted by appropriate selection of feedback resistor Rf, prevents harmful oscillations which might damage the MOSFETs.

Appropriate selection of resistors and capacitors for the sensing and reference inputs ensure that V− exceeds V+ prior to the threshold current through the burden resistor RB, and that V+ lags V−.

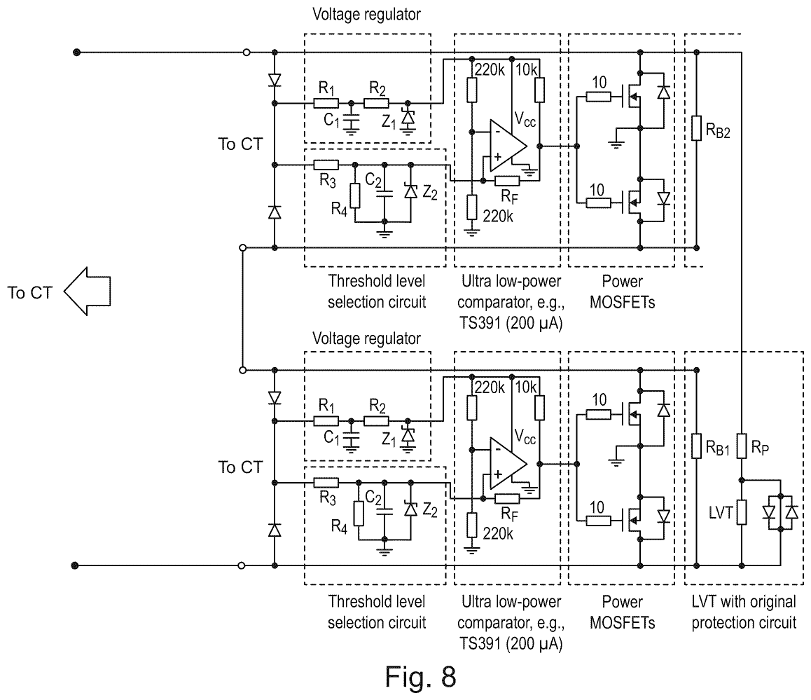

As noted above, the embodiments shown in FIGS. 6 and 7 comprise a single burden resistor for simplicity. The embodiment shown in FIG. 5 comprises three stacked burden resistors RB1, RB2 and RB3 and paired switches S1, S2 and S3. In that example, switches S1, S2 and S3 may be off at low voltages to maximise the voltage across the LVT; switch S1 may be on and switches S2 and S3 off at medium voltages to limit the voltage across the LVT; switches S1 and S2 may be on and S3 off at high voltages to limit the excess voltage across the LVT; and all switches may be on in the case of abnormal, fault or test currents to protect the LVT. It is therefore envisaged that the embodiments shown in FIGS. 6 and 7 may also stack burden resistor and switch pairs to achieve similar auto-ranging functionality. By way of example, FIG. 8 shows two stacked burden resistors RB1 and RB2, each having its own independent power MOSFET stage, comparator stage, voltage regulator stage and threshold level detection stage (corresponding to the embodiment described above and as shown in FIG. 7). In a similar manner to the embodiment shown in FIG. 5, the components of each circuit will be selected for different switching thresholds. For example, the switching arrangement in parallel with RB1 may be selected to actuate only upon abnormal, fault or test currents, whereas the switching arrangement in parallel with RB2 may be selected to actuate at medium voltages to limit the voltage across the LVT. Such a system accommodates at least two LVT measurement ranges (automatically selected) and a protective range in which the LVT is protected.

The invention provides a signal conditioning stage for a photonic current or voltage transducer which comprises a number of burden resistors and a number of switches in parallel with the burden resistors, the switches operable to short different burden resistors in response to detection of different currents or voltages, and thereby protect the burden resistors and/or adjust the dynamic range of the transducer. Although not limited to use with low voltage transducers of the type described above, the invention enables a hybrid photonic current or voltage sensor with an extended measurement range as compared with the state of the art and (as a result) increased accuracy and signal-to-noise ratio at the lower measurement end. Embodiments of the invention provide a device that is capable of covering both protection and metering ranges, as may be defined and re-defined from time-to-time by relevant standards. A state of the art LVT has a limited useful dynamic range; at low input voltage, the range is limited by the signal-to-noise ratio; and at high input voltage, the range is limited by the LVT voltage withstand. The invention enables an auto-ranging device which increases measurement performance at lower current by deliberately reducing the range for lower currents and increasing the range when certain current level is exceeded, increasing dynamic range without the need for multiple LVTs. Similar range switching allows dynamic range increases in voltage sensing applications too.

Throughout the specification, unless the context demands otherwise, the terms “comprise” or “include”, or variations such as “comprises” or “comprising”, “includes” or “including” will be understood to imply the inclusion of a stated integer or group of integers, but not the exclusion of any other integer or group of integers.

Various modifications to the above-described embodiments may be made within the scope of the invention, and the invention extends to combinations of features other than those expressly claimed herein.

1. A photonic transducer signal conditioning stage comprising:
a plurality of burden resistors; and
a plurality of switches, each switch in parallel with a corresponding burden resistor;
wherein each of the burden resistors is different; and
wherein each of the switches is operable to short the corresponding burden resistor responsive to detection of a corresponding threshold current or voltage.

2. The photonic transducer signal conditioning stage of claim 1, wherein one or more of the switches are operable to short the one or more corresponding burden resistors only in the event of abnormal, fault or test currents.

3. The photonic transducer signal conditioning stage of claim 1, wherein the signal conditioning stage is operable to automatically switch detection range so as to increase the dynamic range of the PCT/PVT.

4. The photonic transducer signal conditioning stage of claim 1, wherein the signal conditioning stage comprises two burden resistors and two corresponding switches.

5. The photonic transducer signal conditioning stage of claim 1, wherein the signal conditioning stage is configured such that the or each switch is off by default to maximise the burden resistance of the signal conditioning stage at low input current.

6. The photonic transducer signal conditioning stage of claim 1, wherein the or each switch comprises a solid-state switch, wherein the solid-state switch optionally comprises one or more MOSFETs, and optionally comprises a bi-directional MOSFET switch.

7. The photonic transducer signal conditioning stage of claim 1, wherein the or each switch is controlled by an electronic driver comprising two or more Zener diodes selected for a desired current or voltage threshold.

8. The photonic transducer signal conditioning stage of claim 1, wherein the or each switch is controlled by a comparator.

9. The photonic transducer signal conditioning stage of claim 8, further comprising a threshold selection circuit that provides a non-inverting input to the comparator.

10. The photonic transducer signal conditioning stage of claim 8, further comprising a voltage regulator that provides an inverting input to the comparator.

11. The photonic transducer signal conditioning stage of claim 8, further comprising a positive feedback to the non-inverting input of the comparator via a resistor selected to effect hysteresis sufficient to prevent switching oscillations.

12. The photonic transducer signal conditioning stage of claim 1, wherein the or each switch is controlled by a microcontroller.

13. A photonic current transducer comprising:
a current transformer,
a photonic transducer signal conditioning stage according to claim 1, and
an optical voltage sensor comprising a fibre Bragg grating mechanically coupled to a piezoelectric actuator which expands and contracts responsive to the voltage across the plurality of burden resistors of the signal conditioning stage.

14. A photonic voltage transducer comprising:
a voltage transformer or voltage divider;
a photonic transducer signal conditioning stage according to claim 1; and
an optical voltage sensor comprising a fibre Bragg grating mechanically coupled to a piezoelectric actuator which expands and contracts responsive to the voltage across the plurality of burden resistors of the signal conditioning stage.

15. A monitoring system comprising:
one or more photonic current transducers according to claim 13 and/or one or more photonic voltage transducers according to claim 14; and
an interrogator in optical communication with the one or more photonic voltage and/or current transducers via an optical fibre.

16. The monitoring system of claim 15, comprising a plurality of photonic voltage and/or current transducers, wherein the interrogator is configured to illuminate the optical fibre, receive a corresponding plurality of optical signals from the photonic transducers, and determine the or each sensed voltage from the received optical signal.

17. The monitoring system of claim 16, wherein the or each sensed voltage is determined from a spectral position of a peak reflection wavelength from the or each fibre Bragg grating of respective photonic voltage transducers, and changes in the sensed voltage are determined from changes in the peak reflection wavelength.

18. The monitoring system of claim 15, wherein the interrogator is configured to identify changes in a sensed voltage which correspond to range-switching in a signal conditioning stage of a photonic voltage or current transducer.

19. The monitoring system of claim 18, wherein the output from the interrogator is adjusted or re-calibrated responsive to an identified range-switch.

20. The monitoring system of claim 15, wherein the interrogator is configured to identify a power network fault at or near a particular photonic voltage or current transducer based on changes in the sensed voltage.

21. The monitoring system of claim 15, wherein the fibre Bragg grating of the or each photonic voltage and/or current transducer has a unique peak reflection wavelength, and the interrogator comprises a wavelength division multiplexer.

22. The monitoring system of claim 15, wherein the interrogator comprises a time division multiplexer.
